(19) United States
(12) Patent Application Publication
(10) Pub. No.: US 2026/0074660 A1
(43) Pub. Date: Mar. 12, 2026

(54) VOLTAGE GENERATING CIRCUIT

(71) Applicant: Mitsubishi Electric Corporation, Tokyo (JP)

(72) Inventors: Shinji TAKEZOE, Tokyo (JP); Koji TSUTSUMI, Tokyo (JP)

(73) Assignee: Mitsubishi Electric Corporation, Tokyo (JP)

(21) Appl. No.: 19/384,166

(22) Filed: Nov. 10, 2025

Related U.S. Application Data
(63) Continuation of application No. PCT/JP2023/023246, filed on Jun. 23, 2023.

(51) Int. Cl. H03F 3/217; H03F 1/02

(52) U.S. Cl. CPC H03F 3/2171; H03F 1/0222; H03F 2200/102; H03F 2200/351

(57) ABSTRACT

A voltage generating includes a driver and an amplifier, and the driver circuit outputs the first drive signal and the second drive signal on a basis of a high side input signal, and when a duty ratio of the high side input signal is lower than a predetermined duty ratio, and a pulse width of the high side input signal is decreased, and the driver circuit increases a pulse width of the outputted first drive signal and the amplifier includes a first switching and a second switching element, and the amplifier outputs the PWM signal which is a signal in antiphase with the first drive signal and in phase with the second drive signal in response to on-and-off states of the first switching element and the second switching element.

### CROSS REFERENCE TO RELATED APPLICATION

This application is a Continuation of PCT International Application No. PCT/JP2023/023246, filed on June 23, 2023, which is hereby expressly incorporated by reference into the present application.

### TECHNICAL FIELD

The present disclosure relates to a voltage generating circuit.

### BACKGROUND ART

There are known envelope tracking amplifiers as conventional high efficiency amplifiers. An envelope tracking amplifier is an amplifier to achieve a state close to saturated operation at all times, and improve power efficiency, by dynamically changing the drain voltage of a transistor in the amplifier on the basis of the envelope (envelope) of an input signal. Here, for example, a GaN circuit is used in order to dynamically change the drain voltage described above on the basis of the envelope of the input signal (e.g. Non-Patent Literature 1).

A configuration example of a drain voltage generating circuit used for an envelope tracking amplifier is illustrated in FIG. 10. As illustrated in FIG. 10 for example, the drain voltage generating circuit mainly includes an upstream driver circuit and a downstream GaN circuit (amplifier). The driver circuit outputs two PWM signals (IN+: high side signal, IN-: low side signal) in response to an input of a PWM signal (hereinafter, also referred to as an "input PWM signal") which is an input signal. At this time, the high side signal is output in phase with the input PWM signal, and the low side signal is output in antiphase with the input PWM signal.

The GaN circuit is driven by the two PWM signals (the high side signal, the low side signal) output from the driver circuit, and outputs a PWM signal (hereinafter, also referred to as an "output PWM signal") corresponding to the input PWM signal input to the driver circuit. At this time, the output PWM signal is output in antiphase with the high side signal, and in phase with the low side signal. That is, the output PWM signal is a signal whose logic is inverted from the logic of the input PWM signal. The output PWM signal output from the GaN circuit is flattened (time-averaged) by an LPF, and a signal obtained thereby is output as a signal representing the drain voltage described above (Vout in FIG. 10).

### CITATION LIST

### PATENT LITERATURE

Non-Patent Literature 1: Saiki, et al., "High Speed and High Efficiency GaN Switching Mode Envelope Amplifier with 80MHz Modulation Bandwidth Operation," IEICE 2021 Society Conference

### SUMMARY OF INVENTION

### TECHNICAL PROBLEM

Here, in order for a signal Vout output from the drain voltage generating circuit to precisely track the envelope of the input signal input to the amplifier, the GaN circuit needs to output, as the output PWM signal, a signal representing an output voltage (the time integrated value of output pulses) accurately proportional to the duty ratio of the input PWM signal input to the driver circuit. However, there is a problem that the precision of the output voltage of the drain voltage generating circuit deteriorates due to the influence of the rise time and falling time (trf: time raise fall) of the output PWM signal output from the GaN circuit in an area where the duty ratio of the input PWM signal input to the driver circuit is close to 0% or 100%.

For example, there is a problem that, when the duty ratio of the input PWM signal input to the driver circuit becomes lower than a predetermined duty ratio in a case where the trf of the output PWM signal output from the GaN circuit is long, the relationship of the output voltage of the drain voltage generating circuit to the duty ratio of the input PWM signal becomes non-linear. FIG. 11 illustrates the relationship between the duty ratio of the input PWM signal input to the driver circuit and the output voltage of the drain voltage generating circuit. It is assumed in the configuration in the present example that, as described above, the input PWM signal input to the driver circuit and the output PWM signal output from the GaN circuit have inverted logics, and, as illustrated in FIG. 11, a signal obtained by inverting the logic of the high side signal output from the driver circuit is output from the GaN circuit as the output PWM signal.

It is assumed that the duty ratio of the input PWM signal input to the driver circuit becomes lower than the predetermined duty ratio represented by the reference sign x, that is, it is assumed that a signal with a pulse width smaller than the sum of the rise time and fall time of the output PWM signal output from the GaN circuit has been input as the input PWM signal to the driver circuit. At this time, in a case where the trf of the output PWM signal output from the GaN circuit is long, the output PWM signal cannot fall sufficiently. Accordingly, the equivalent pulse width of the output PWM signal increases, and the output voltage of the drain voltage generating circuit increases. Thereby, in the area on the left side of the reference sign x illustrated in FIG. 11, the linearity of the output voltage of the drain voltage generating circuit in relation to the duty ratio of the input PWM signal collapses in some cases. Accordingly, in order to keep the linearity, it is necessary to lower the output voltage of the drain voltage generating circuit (the voltage represented by the output PWM signal output from the GaN circuit) in the area where the duty ratio of the input PWM signal becomes lower than the predetermined duty ratio.

The present disclosure has been made to solve the problem described above, and an object thereof is to obtain a driver circuit that drives an amplifier to output an output PWM signal representing an output voltage, and can improve the linearity of the output voltage represented by the output PWM signal described above in relation to the duty ratio of an input PWM signal.

### SOLUTION TO PROBLEM

A voltage generating circuit according to the present disclosure includes an amplifier to output an output PWM signal representing an output voltage and a driver circuit to output a first drive signal and a second drive signal for driving the amplifier, wherein on a basis of a high side input signal obtained from an input PWM signal which is a PWM signal input to the driver circuit, the driver circuit outputs the first drive signal which is a PWM signal in phase with the high side input signal, and the second drive signal which is a PWM signal in antiphase with the high side input signal, and when a duty ratio of the high side input signal is lower than a predetermined duty ratio, and a pulse width of the high side input signal is decreased, the driver circuit increases a pulse width of the outputted first drive signal before the pulse width of the high side input signal is decreased with respect to the pulse width of the first drive signal outputted in response to the high side input signal, and the amplifier includes a first switching element that is turned on and off in response to the first drive signal output from the driver circuit, and a second switching element that is connected with the first switching element and turned on and off in response to a second drive signal outputted from the driver circuit, and the amplifier outputs the output PWM signal which is a signal in antiphase with the first drive signal and in phase with the second drive signal in response to on-and-off states of the first switching element and the second switching element.

### ADVANTAGEOUS EFFECTS OF INVENTION

The present disclosure can obtain a driver circuit that drives an amplifier to output an output PWM signal representing an output voltage, and can improve the linearity of the output voltage represented by the output PWM signal described above in relation to the duty ratio of an input PWM signal.

### BRIEF DESCRIPTION OF DRAWINGS

FIG. 1 is a diagram illustrating a configuration example of a driver circuit according to a first embodiment.

FIG. 2 is a diagram illustrating a configuration example of an SW signal generating circuit in the first embodiment.

FIG. 3 is a diagram illustrating configuration examples of a first control signal generating circuit and a second control signal generating circuit in the first embodiment.

FIG. 4 is a diagram illustrating a configuration example of a first logical operation circuit in the first embodiment.

FIG. 5 is a diagram illustrating a configuration example of a second logical operation circuit in the first embodiment.

FIG. 6 is a timing chart illustrating an operation example of a driver circuit 1 according to the first embodiment, and is a timing chart of each signal in a case where pulse width correction is performed.

FIG. 7A is a timing chart of each signal processed in the first logical operation circuit in a case where pulse width correction is not performed in the first embodiment.

FIG. 7B is a timing chart of each signal processed in the second logical operation circuit in a case where pulse width correction is not performed in the first embodiment.

FIG. 7C is a timing chart of each signal processed in the first logical operation circuit in a case where pulse width correction is performed in the first embodiment.

FIG. 7D is a timing chart of each signal processed in the second logical operation circuit in a case where pulse width correction is performed in the first embodiment.

FIG. 8A is a truth table of each signal processed in the first logical operation circuit in a case where a discharge voltage from a capacitor is equal to or lower than a threshold voltage in the first embodiment.

FIG. 8B is a truth table of each signal processed in the first logical operation circuit in a case where the discharge voltage from the capacitor exceeds the threshold voltage in the first embodiment.

FIG. 9A is a truth table of each signal processed in the second logical operation circuit in a case where the discharge voltage from the capacitor is equal to or lower than the threshold voltage in the first embodiment.

FIG. 9B is a truth table of each signal processed in the second logical operation circuit in a case where the discharge voltage from the capacitor exceeds the threshold voltage in the first embodiment.

FIG. 10 is a diagram illustrating a configuration example of a conventional drain voltage generating circuit.

FIG. 11 is a drawing illustrating the relationship between the duty ratio of an input PWM signal input to a driver circuit in the conventional drain voltage generating circuit and the output voltage of the drain voltage generating circuit.

### DESCRIPTION OF EMBODIMENTS

Hereinbelow, an embodiment of the present disclosure is explained in detail with reference to the drawings.

### First Embodiment.

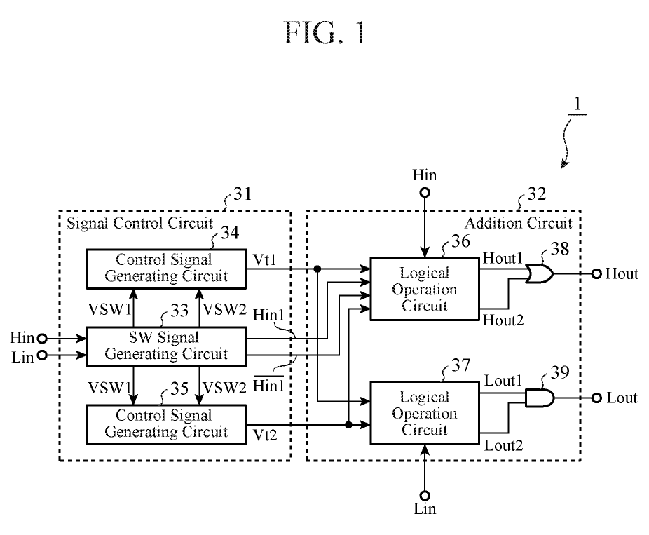

FIG. 1 is a diagram illustrating a configuration example of a driver circuit 1 according to a first embodiment. The driver circuit 1 illustrated in FIG. 1 drives a GaN circuit included in a drain voltage generating circuit used for an envelope tracking amplifier. The driver circuit 1 receives an input of an input PWM signal, and generates two PWM signals (Hout, Lout) for driving the GaN circuit. Among them, Hout is equivalent to the high side signal mentioned above, and Lout is equivalent to the low side signal mentioned above. Note that the signal Hout is also referred to as a "first drive signal," and the signal Lout is also referred to as a "second drive signal" in the following explanation. As illustrated in FIG. 1 for example, the driver circuit 1 includes a signal control circuit 31 and an addition circuit 32.

### <Signal Control Circuit 31>

The signal control circuit 31 is a circuit to generate signals Vt1 and Vt2 for performing pulse width correction on the two PWM signals (Hout, Lout) for driving the GaN circuit using a high side input signal Hin and a low side input signal Lin obtained from the input PWM signal input to the driver circuit 1. Note that the signals Vt1 and Vt2 are also referred to as "correction pulses" in the following explanation. As illustrated in FIG. 1 for example, the signal control circuit 31 includes an SW signal generating circuit 33, a control signal generating circuit (first control signal generating circuit) 34, and a control signal generating circuit (second control signal generating circuit) 35.

The SW signal generating circuit 33 generates a signal VSW1 and a signal VSW2 using the high side input signal Hin and the low side input signal Lin, and outputs the generated signal VSW1 and signal VSW2 to the control signal generating circuit 34 and the control signal generating circuit 35. In addition, the SW signal generating circuit 33 generates a signal Hin1 and a signal /Hin1 using the high side input signal Hin and the low side input signal Lin, and outputs the generated signal Hin1 and signal /Hin1 to the addition circuit 32. Note that the signal /Hin1 is a signal obtained by inverting the signal Hin1, and "/" represents an overbar.

The control signal generating circuit 34 generates a signal Vt1 for performing pulse width correction on the two PWM signals (Hout, Lout) described above using the signal VSW1 and the signal VSW2 output from the SW signal generating circuit 33, and outputs the generated signal Vt1 to the addition circuit 32.

The control signal generating circuit 35 generates a signal Vt2 for performing pulse width correction on the two PWM signals (Hout, Lout) described above using the signal VSW1 and the signal VSW2 output from the SW signal generating circuit 33, and outputs the generated signal Vt2 to the addition circuit 32.

### <Addition Circuit 32>

The addition circuit 32 is a circuit to perform pulse width correction on the signals Hout and Lout using the signals Vt1 and Vt2 generated by the signal control circuit 31 (control signal generating circuits 34 and 35). As illustrated in FIG. 1 for example, the addition circuit 32 includes a logical operation circuit (first logical operation circuit) 36, a logical operation circuit (second logical operation circuit) 37, a OR circuit 38, and a AND circuit 39.

The logical operation circuit 36 is a circuit to add, to the high side input signal Hin of the driver circuit 1, the signals Vt1 and Vt2 generated by the signal control circuit 31 (control signal generating circuits 34 and 35). The logical operation circuit 36 calculates signals Hout1 and Hout2 by the addition, and outputs the calculated signals Hout1 and Hout2 to the OR circuit 38.

The logical operation circuit 37 is a circuit to add, to the low side input signal Lin of the driver circuit 1, the signal Vt1 and the signal Vt2 generated by the signal control circuit 31 (control signal generating circuits 34 and 35). The logical operation circuit 37 calculates a signal Lout1 and a signal Lout2 by the addition, and outputs the calculated signal Lout1 and signal Lout2 to the AND circuit 39.

The OR circuit 38 computes the logical sum of the signals Hout1 and Hout2 output from the logical operation circuit 36, and outputs the obtained signal Hout. The AND circuit 39 computes the logical product of the signal Lout1 and the signal Lout2 output from the logical operation circuit 37, and outputs the obtained signal Lout.

For example, the signal Hout output from the OR circuit 38 and the signal Lout output from the AND circuit 39 are input signals of the GaN circuit connected downstream of the driver circuit 1. The GaN circuit is driven by the input signals Hout and Lout, and outputs a signal representing an output voltage on the basis of the duty ratio of the input PWM signal input to the driver circuit 1.

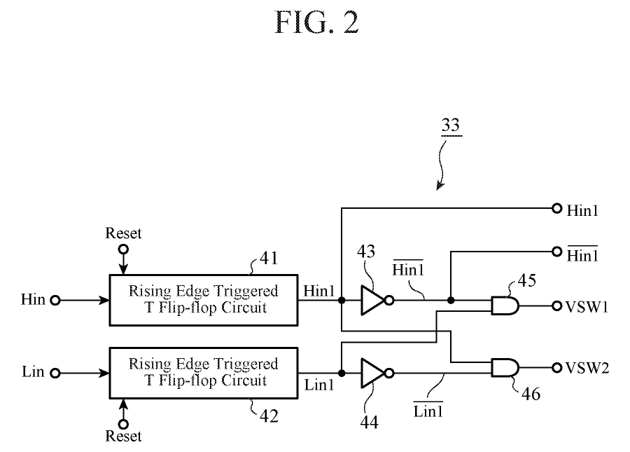

Next, a configuration example of each circuit described above is explained. <SW Signal Generating Circuit 33> FIG. 2 is a diagram illustrating a configuration example of the SW signal generating circuit 33. As illustrated in FIG. 2 for example, the SW signal generating circuit 33 includes rising edge triggered T flip-flop circuits 41 and 42, inverter circuits 43 and 44, and AND circuits 45 and 46.

The rising edge triggered T flip-flop circuit 41 is a circuit that can obtain a desired voltage waveform by system resetting, receives an input of the high side input signal Hin, and generates the signal Hin1. The rising edge triggered T flip-flop circuit 41 outputs the generated signal Hin1 to the logical operation circuit 36, the inverter circuit 43, and the AND circuit 46.

The rising edge triggered T flip-flop circuit 42 is a circuit that can obtain a desired voltage waveform by system resetting, receives an input of the low side input signal Lin, and generates a signal Lin1. The rising edge triggered T flip-flop circuit 42 outputs the generated signal Lin1 to the inverter circuit 44 and the AND circuit 45.

The inverter circuit 43 generates a signal /Hin1 which is a signal obtained by inverting the signal Hin1. The inverter circuit 43 outputs the generated signal /Hin1 to the logical operation circuit 36 and the AND circuit 45.

The inverter circuit 44 generates a signal /Lin1 which is a signal obtained by inverting the signal Lin1. The inverter circuit 44 outputs the generated signal /Lin1 to the AND circuit 46.

The AND circuit 45 computes the logical product of the signal /Hin1 and the signal Lin1, and outputs the obtained signal VSW1 to the control signal generating circuits 34 and 35.

The AND circuit 46 computes the logical product of the signal Hin1 and the signal /Lin1, and outputs the obtained signal VSW2 to the control signal generating circuits 34 and 35. These signals VSW1 and VSW2 specify the charging time of capacitors 516 included in the control signal generating circuits 34 and 35 mentioned later.

### <Control Signal Generating Circuits 34 and 35>

FIG. 3 is a diagram illustrating configuration examples of the control signal generating circuits 34 and 35. As illustrated in FIG. 3 for example, the control signal generating circuits 34 and 35 include switches 511 and 512, resistors 513 to 515, the capacitor 516, and a switch 517. Note that basic configuration examples of the control signal generating circuits 34 and 35 are identical to each other, and only signals input to respective elements are different from each other. Accordingly, here, the configuration examples of both the circuits are explained together using a single drawing.

In the control signal generating circuits 34 and 35, the switch 511, the resistor 513, the switch 512, and the resistor 515 are connected in series between a power supply voltage Vdd and the ground. In addition, in the control signal generating circuits 34 and 35, the capacitor 516 and the resistor 514 are connected in parallel between a signal line linking the resistor 513 and the switch 512 and the ground.

In addition, in the control signal generating circuits 34 and 35, the switch 517 having a threshold voltage Vth is connected between the signal line linking the resistor 513 and the switch 512 and an output terminal to output the signal Vt1 or Vt2.

The signal VSW1 or VSW2 is input to the switches 511 and 512. Specifically, in the control signal generating circuit 34, the signal VSW1 is input to the switch 511, and the signal VSW2 is input to the switch 512. In addition, in the control signal generating circuit 35, the signal VSW2 is input to the switch 511, and the signal VSW1 is input to the switch 512. ON/OFF control of the switches 511 and 512 is performed on the basis of the signal VSW1 or VSW2.

In addition, ON/OFF control of the switch 517 is performed on the basis of the magnitude relationship between a discharge voltage VM1 or VM2 from the capacitor 516 and the threshold voltage Vth of the switch 517. Specifically, in the control signal generating circuit 34, ON/OFF control of the switch 517 is performed on the basis of the magnitude relationship between the discharge voltage VM1 from the capacitor 516 and the threshold voltage Vth. In the control signal generating circuit 34, the switch 517 is turned on in a case where the discharge voltage VM1 from the capacitor 516 exceeds the threshold voltage Vth. When the switch 517 has been turned on, the signal Vt1 for performing the pulse width correction described above is output (the level of the signal Vt1 becomes High).

In addition, in the control signal generating circuit 35, ON/OFF control of the switch 517 is performed on the basis of the magnitude relationship between the discharge voltage VM2 from the capacitor 516 and the threshold voltage Vth. In the control signal generating circuit 35, the switch 517 is turned on in a case where the discharge voltage VM2 from the capacitor 516 exceeds the threshold voltage Vth. When the switch 517 has been turned on, the signal Vt2 for performing the pulse width correction described above is output (the level of the signal Vt2 becomes High).

### <Logical Operation Circuit 36>

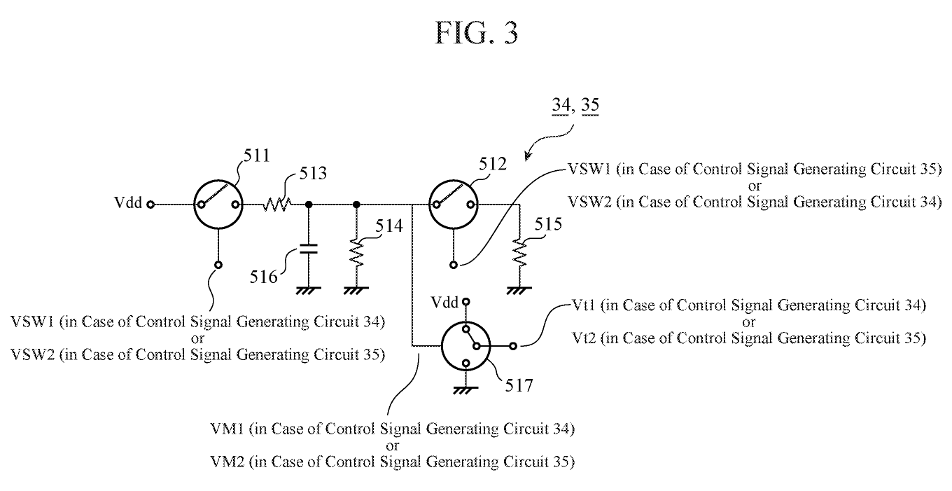

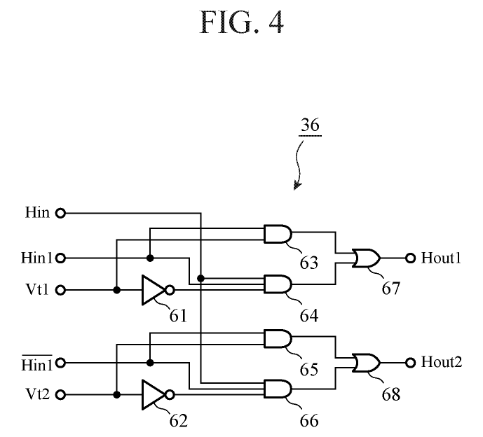

FIG. 4 is a diagram illustrating a configuration example of the logical operation circuit 36. As illustrated in FIG. 4 for example, the logical operation circuit 36 include inverter circuits 61 and 62, AND circuits 63 to 66, and OR circuits 67 and 68.

The inverter circuit 61 generates the signal /Vt1 which is a signal obtained by inverting the signal Vt1 output from the control signal generating circuit 34. The inverter circuit 61 outputs the generated signal /Vt1 to the AND circuit 64.

The inverter circuit 62 generates the signal /Vt2 which is a signal obtained by inverting the signal Vt2 output from the control signal generating circuit 35. The inverter circuit 62 outputs the generated signal /Vt2 to the AND circuit 66.

The AND circuit 63 computes the logical product of the signal Hin1 output from the SW signal generating circuit 33 and the signal Vt1, and outputs the obtained signal to the OR circuit 67.

The AND circuit 64 computes the logical product of the high side input signal Hin of the driver circuit 1, the signal Hin1 output from the SW signal generating circuit 33, and the signal /Vt1 output from the inverter circuit 61, and outputs the obtained signal to the OR circuit 67.

The AND circuit 65 computes the logical product of the signal /Hin1 output from the SW signal generating circuit 33 and the signal Vt2, and outputs the obtained signal to the OR circuit 68.

The AND circuit 66 computes the logical product of the high side input signal Hin of the driver circuit 1, the signal /Hin1 output from the SW signal generating circuit 33, and the signal /Vt2 output from the inverter circuit 62, and outputs the obtained signal to the OR circuit 68.

The OR circuit 67 computes the logical sum of the signals output from the AND circuits 63 and 64, and outputs the obtained signal Hout1 to the OR circuit 38.

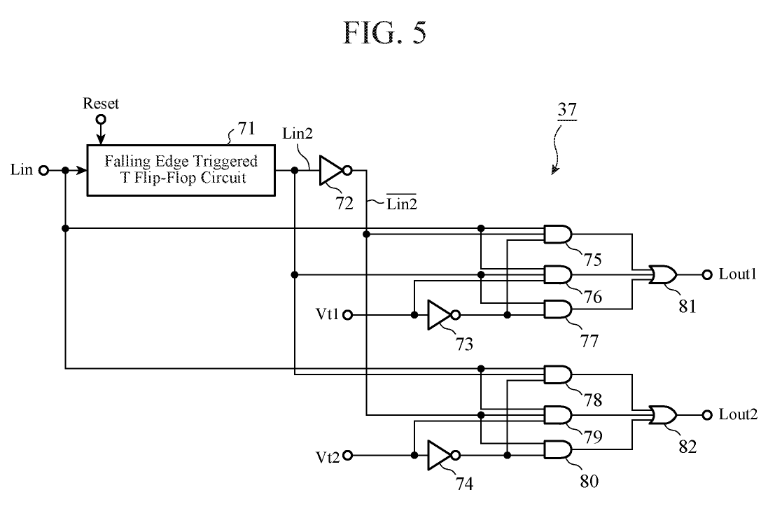

The OR circuit 68 computes the logical sum of the signals output from the AND circuits 65 and 66, and outputs the obtained signal Hout2 to the OR circuit 38.

<Logical Operation Circuit 37> FIG. 5 is a diagram illustrating a configuration example of the logical operation circuit 37. As illustrated in FIG. 5 for example, the logical operation circuit 37 includes a falling edge triggered T flip-flop circuit 71, inverter circuits 72 to 74, AND circuits 75 to 80, and OR circuits 81 and 82.

The falling edge triggered T flip-flop circuit 71 is a circuit that can obtain a desired voltage waveform by system resetting, receives an input of the low side input signal Lin, and generates a signal Lin2. The falling edge triggered T flip-flop circuit 71 outputs the generated signal Lin2 to the inverter circuit 72 and the AND circuits 76 and 78.

The inverter circuit 72 generates a signal /Lin2 which is a signal obtained by inverting the signal Lin2. The inverter circuit 72 outputs the generated signal /Lin2 to the AND circuits 75, 79, and 80.

The inverter circuit 73 generates a signal /Vt1 which is a signal obtained by inverting the signal Vt1 output from the control signal generating circuit 34. The inverter circuit 73 outputs the generated signal /Vt1 to the AND circuits 75 and 77.

The inverter circuit 74 generates a signal /Vt2 which is a signal obtained by inverting the signal Vt2 output from the control signal generating circuit 35. The inverter circuit 74 outputs the generated signal /Vt2 to the AND circuits 78 and 80.

The AND circuit 75 computes the logical product of the low side input signal Lin, the signal /Lin2 output from the inverter circuit 72, and the signal /Vt1 output from the inverter circuit 73, and outputs the obtained signal to the OR circuit 81.

The AND circuit 76 computes the logical product of the low side input signal Lin, the signal Lin2 output from the falling edge triggered T flip-flop circuit 71, and the signal Vt1 output from the control signal generating circuit 34, and outputs the obtained signal to the OR circuit 81.

The AND circuit 77 computes the logical product of the signal Vt1 output from the control signal generating circuit 34 and the signal /Vt1 output from the inverter circuit 73, and outputs the obtained signal to the OR circuit 81.

The AND circuit 78 computes the logical product of the low side input signal Lin, the signal Lin2 output from the falling edge triggered T flip-flop circuit 71, and the signal /Vt2 output from the inverter circuit 74, and outputs the obtained signal to the OR circuit 82.

The AND circuit 79 computes the logical product of the low side input signal Lin, the signal /Lin2 output from the inverter circuit 72, and the signal Vt2 output from the control signal generating circuit 35, and outputs the obtained signal to the OR circuit 82.

The AND circuit 80 computes the logical product of the signal /Lin2 output from the inverter circuit 72 and the signal /Vt2 output from the inverter circuit 74, and outputs the obtained signal to the OR circuit 82.

The OR circuit 81 computes the logical sum of the signals output from the AND circuits 75 to 77, and outputs the obtained signal Lout1 to the AND circuit 39.

The OR circuit 82 computes the logical sum of the signals output from the AND circuits 78 to 80, and outputs the obtained signal Lout2 to the AND circuit 39.

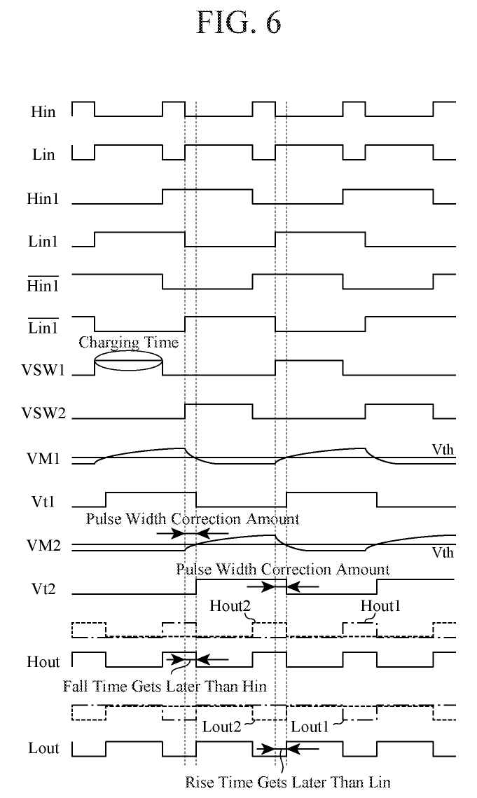

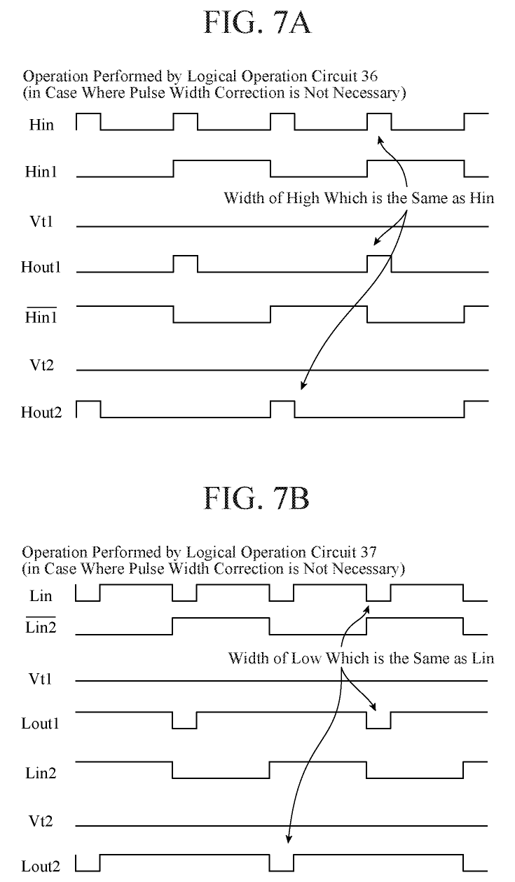

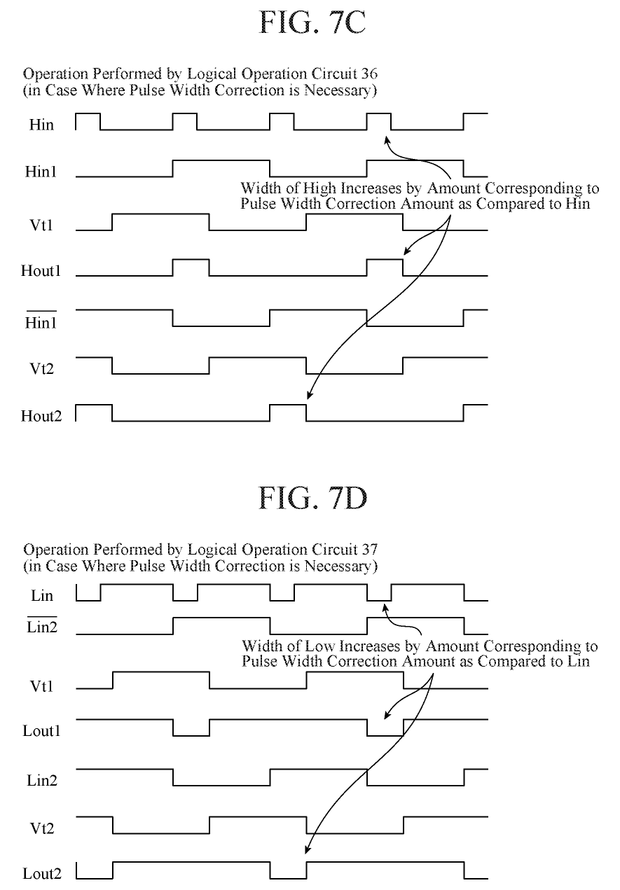

Next, an operation example of the driver circuit 1 according to the first embodiment is explained with reference to timing charts illustrated in FIGS. 6 and 7A to 7D.

In the timing charts illustrated in FIGS. 6 and 7A to 7D, the horizontal axes represent time. In addition, Hin, Lin, Hin1, Lin1, /Hin1, /Lin1, Lin2, /Lin2, VSW1, VSW2, VM1, Vt1, VM2, Vt2, Hout1, Hout2, Lout1, Lout2, Hout, and Lout illustrated along the vertical axes are input signals input to respective nodes and output signals output from respective nodes illustrated in FIGS. 1 to 5. In the charts, the voltage waveforms of the respective input signals and the respective output signals are represented as binary waveforms that are either at the High level or the Low level.

Note that FIG. 6 illustrates a timing chart of each signal in a case where pulse width correction is performed. In addition, FIG. 7A illustrates a timing chart of each signal processed in the logical operation circuit 36 in a case where pulse width correction is not performed, and FIG. 7B illustrates a timing chart of each signal processed in the logical operation circuit 37 in a case where pulse width correction is not performed. In addition, FIG. 7C illustrates a timing chart of each signal processed in the logical operation circuit 36 in a case where pulse width correction is performed, and FIG. 7D illustrates a timing chart of each signal processed in the logical operation circuit 37 in a case where pulse width correction is performed.

First, the SW signal generating circuit 33 generates the signal Hin1 from the high side input signal Hin of the driver circuit 1 via the rising edge triggered T flip-flop circuit 41. In addition, the SW signal generating circuit 33 generates the signal Lin1 from the low side input signal Lin of the driver circuit 1 via the rising edge triggered T flip-flop circuit 42.

In addition, the SW signal generating circuit 33 generates the signal VSW1 representing the logical product of the signal /Hin1 which is a signal obtained by inverting the logic of the high side input signal Hin and the signal Lin1 via the inverter circuit 43 and the AND circuit 45.

In addition, the SW signal generating circuit 33 generates the signal VSW2 representing the logical product of the signal /Lin1 which is a signal obtained by inverting the logic of the signal Lin1 and the signal Hin1 via the inverter circuit 44 and the AND circuit 46.

The signals VSW1 and VSW2 generated by the SW signal generating circuit 33 control the switches 511 and 512 of the control signal generating circuits 34 and 35.

Specifically, ON/OFF control of the switch 511 of the control signal generating circuit 34 is performed by the signal VSW1, and ON/OFF control of the switch 512 of the control signal generating circuit 34 is performed by the signal VSW2. Charging and discharging of the capacitor 516 are controlled in the control signal generating circuit 34 by the operation performed by these switches.

For example, in the control signal generating circuit 34, when the signal VSW1 is at the High level, the switch 511 is turned on, thereby charging the capacitor 516. Then, when the level of the signal VSW2 becomes High after the level of the signal VSW1 has become Low, the switch 511 is turned off, the switch 512 is turned on, and discharging from the capacitor 516 is performed.

If the discharge voltage VM1 from the capacitor 516 exceeds the threshold voltage Vth of the switch 517 at this time, the switch 517 is connected to the side of the power supply voltage Vdd (turned on). Thereby, the level of the signal Vt1 output from the control signal generating circuit 34 becomes High. On the other hand, if the discharge voltage VM1 from the capacitor 516 is equal to or lower than the threshold voltage Vth of the switch 517, the switch 517 is connected to the side of the ground (turned off). Thereby, the level of the signal Vt1 output from the control signal generating circuit 34 becomes Low.

As a result, the signal Vt1 is output from the control signal generating circuit 34 in the form illustrated in FIG. 6, for example. At this time, the signal Vt1 has a pulse width inversely proportional to the length of time for which the high side input signal Hin is at the High level. In addition, a fall start time of the signal Vt1 gets later than a fall start time of the high side input signal Hin by an amount corresponding to a pulse width correction amount illustrated in FIG. 6.

Similarly, in the control signal generating circuit 35, ON/OFF control of the switch 511 is performed by the signal VSW2, and ON/OFF control of the switch 512 is performed by the signal VSW1. Charging and discharging of the capacitor 516 are controlled in the control signal generating circuit 35 by the operation performed by these switches.

For example, in the control signal generating circuit 35, when the signal VSW2 is at the High level, the switch 511 is turned on, thereby charging the capacitor 516. Then, when the level of the signal VSW1 becomes High after the level of the signal VSW2 has become Low, the switch 511 is turned off, the switch 512 is turned on, and discharging from the capacitor 516 is performed.

If the discharge voltage VM2 from the capacitor 516 exceeds the threshold voltage Vth of the switch 517 at this time, the switch 517 is connected to the side of the power supply voltage Vdd (turned on). Thereby, the level of the signal Vt2 output from the control signal generating circuit 35 becomes High. On the other hand, if the discharge voltage VM2 from the capacitor 516 is equal to or lower than the threshold voltage Vth of the switch 517, the switch 517 is connected to the side of the ground (turned off). Thereby, the level of the signal Vt2 output from the control signal generating circuit 35 becomes Low.

As a result, the signal Vt2 is output from the control signal generating circuit 35 in the form illustrated in FIG. 6, for example. At this time, the signal Vt2 has a pulse width inversely proportional to the length of time for which the high side input signal Hin is at the High level. In addition, a fall start time of the signal Vt2 gets later than a rise start time of the low side input signal Lin by an amount corresponding to a pulse width correction amount illustrated in FIG. 6.

By adding the signals Vt1 and Vt2 described above to the high side input signal Hin of the driver circuit 1, the logical operation circuit 36 outputs the signals Hout1 and Hout2.

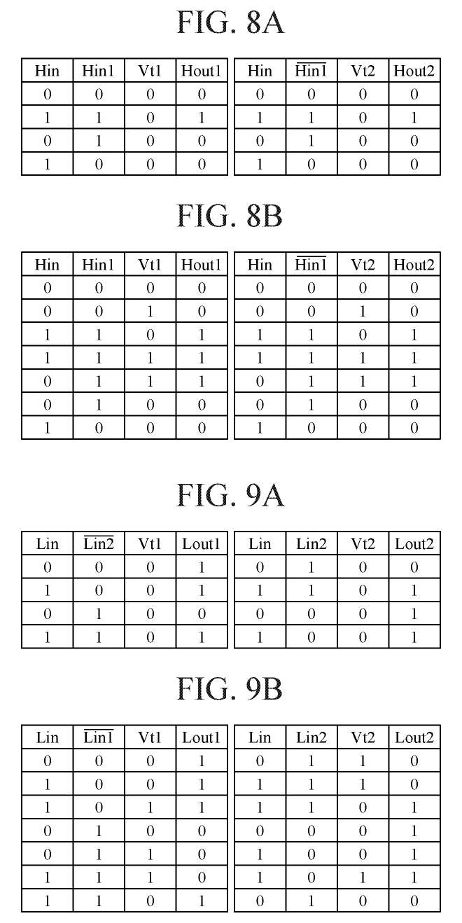

Here, a truth table of each signal in the logical operation circuit 36 is illustrated in FIG. 8A and FIG. 8B. FIG. 8A illustrates a truth table in a case where the discharge voltages VM1 and VM2 from the capacitors 516 are equal to or lower than the threshold voltage Vth of the switches 517. Since the discharge voltages VM1 and VM2 from the capacitors 516 are equal to or lower than the threshold voltage Vth of the switches 517 in FIG. 8A, the signals Vt1 and Vt2 are always 0.

In this case, the logical operation circuit 36 does not perform pulse width correction on the high side input signal Hin. That is, the logical operation circuit 36 generates the signals Hout1 and Hout2 as in the truth table illustrated in FIG. 8A, and outputs the generated signals Hout1 and Hout2 to the OR circuit 38 (see FIG. 7A also). Then, the OR circuit 38 outputs the signal Hout representing the logical sum of the signals Hout1 and Hout2 output from the logical operation circuit 36. This signal Hout is a signal representing a waveform similar to the high side input signal Hin (a waveform of the high side input signal Hin for which pulse width correction is not performed).

On the other hand, FIG. 8B illustrates a truth table in a case where the discharge voltages VM1 and VM2 from the capacitors 516 exceed the threshold voltage Vth of the switches 517. Because the discharge voltages VM1 and VM2 from the capacitors 516 exceed the threshold voltage Vth of the switches 517 in FIG. 8B, the signals Vt1 and Vt2 become 1 in some cases.

In this case, the logical operation circuit 36 performs, on the high side input signal Hin, pulse width correction corresponding to a pulse width correction amount that has occurred to the signals Vt1 and Vt2. That is, the logical operation circuit 36 generates the signals Hout1 and Hout2 as in the truth table illustrated in FIG. 8B, and outputs the generated signals Hout1 and Hout2 to the OR circuit 38 (see FIG. 7C also). The OR circuit 38 outputs the signal Hout representing the logical sum of the signals Hout1 and Hout2 output from the logical operation circuit 36. As illustrated in FIG. 6, this signal Hout is a signal representing a waveform having a pulse width (the width of High) which has increased by an amount corresponding to the pulse width correction amount, and having a width of Low which has decreased by the amount corresponding to the pulse width correction amount, as compared with the high side input signal Hin.

On the other hand, by adding the signals Vt1 and Vt2 described above to the low side input signal Lin of the driver circuit 1, the logical operation circuit 37 outputs the signals Lout1 and Lout2.

Here, a truth table of each signal in the logical operation circuit 37 is illustrated in FIG. 9A and FIG. 9B. FIG. 9A illustrates a truth table in a case where the discharge voltages VM1 and VM2 from the capacitors 516 are equal to or lower than the threshold voltage Vth of the switches 517. Since the discharge voltages VM1 and VM2 from the capacitors 516 are equal to or lower than the threshold voltage Vth of the switches 517 in FIG. 9A, the signals Vt1 and Vt2 are always 0.

In this case, the logical operation circuit 37 does not perform pulse width correction on the low side input signal Lin. That is, the logical operation circuit 37 generates the signals Lout1 and Lout2 as in the truth table illustrated in FIG. 9A, and outputs the generated signals Lout1 and Lout2 to the AND circuit 39 (see FIG. 7B also). The AND circuit 39 outputs the signal Lout representing the logical product of the signals Lout1 and Lout2. This signal Lout is a signal representing a waveform similar to the low side input signal Lin (a waveform of the low side input signal Lin for which pulse width correction is not performed).

On the other hand, FIG. 9B illustrates a truth table in a case where the discharge voltages VM1 and VM2 from the capacitors 516 exceed the threshold voltage Vth of the switches 517. Because the discharge voltages VM1 and VM2 from the capacitors 516 exceed the threshold voltage Vth of the switches 517 in FIG. 9B, the signals Vt1 and Vt2 become 1 in some cases.

In this case, the logical operation circuit 37 performs, on the low side input signal Lin, pulse width correction corresponding to a pulse width correction amount that has occurred to the signals Vt1 and Vt2. That is, the logical operation circuit 37 generates the signals Lout1 and Lout2 as in the truth table illustrated in FIG. 9B, and outputs the generated signals Lout1 and Lout2 to the AND circuit 39 (see FIG. 7D also). The AND circuit 39 outputs the signal Lout representing the logical product of the signals Lout1 and Lout2. As illustrated in FIG. 6, this signal Lout is a signal representing a waveform having a pulse width (the width of High) which has decreased by an amount corresponding to the pulse width correction amount, and having a width of Low which has increased by the amount corresponding to the pulse width correction amount, as compared with the low side input signal Lin.

As described above, for example, the signal Hout output from the OR circuit 38 and the signal Lout output from the AND circuit 39 are input signals of the GaN circuit disposed downstream of the driver circuit 1. The GaN circuit outputs a voltage according to the duty ratios of the input signals Hout and Lout.

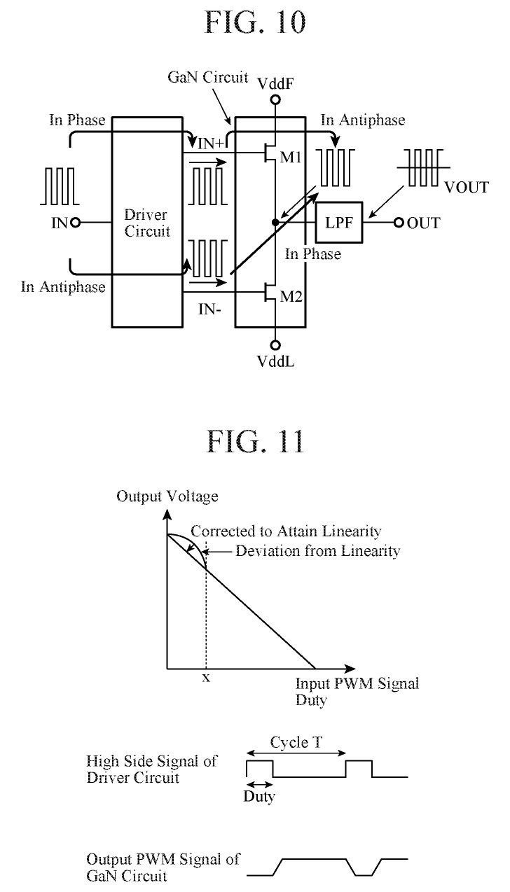

Here, as illustrated in FIG. 10 for example, the GaN circuit includes two transistors M1 and M2, and is used in two states, one of which is a state where the transistor M1 is turned on, and the transistor M2 is turned off, and the other of which is a state where the transistor M1 is turned off, and the transistor M2 is turned on. Accordingly, in the GaN circuit, in a case where, for example, the pulse width of the signal Hout has increased, and the transistor M1 is turned on for an increased length of time, it is necessary to decrease the pulse width of the signal Lout, and increase the length of time for which the transistor M2 is turned off. In addition, the output PWM signal output from the GaN circuit is a signal which is in antiphase with the high side signal (i.e. the signal Hout), and in phase with the low side signal (i.e. the signal Lout), as described above. Accordingly, the pulse width of the output PWM signal output from the GaN circuit decreases by performing the pulse width correction described above in the driver circuit 1 to increase the pulse width of the signal Hout, and decrease the pulse width of the signal Lout; as a result, the output voltage of the GaN circuit can be lowered.

Note that, in a case where the duty ratio of the input PWM signal input to the driver circuit 1 having been in the area where the relationship of the output voltage to the duty ratio is non-linear has increased, that is, in a case where the duty ratio of the input PWM signal input to the driver circuit 1 has transitioned rightward from a point where the duty ratio is slightly smaller than that denoted by a reference sign x illustrated in FIG. 11, the lengths of time for which the signals VSW1 and VSW2 generated from the high side input signal Hin and the low side input signal Lin are at the High levels decrease. Accordingly, in the driver circuit 1, the charging time of the capacitors 516 in the control signal generating circuits 34 and 35 decreases.

In view of this, in the driver circuit 1, the threshold voltage Vth of the switches 517 is set to a voltage which is equal to or higher than the inter-terminal voltage of the capacitors 516 at the time when the duty ratio of the input PWM signal becomes a duty ratio which is sufficiently high to such a degree that it becomes unnecessary to lower the output voltage of the GaN circuit, that is, at the time when the duty ratio of the input PWM signal becomes a predetermined duty ratio denoted by the reference sign x in FIG. 11. Note that the inter-terminal voltage of the capacitors 516 at the time when the duty ratio of the input PWM signal becomes the duty ratio denoted by the reference sign x illustrated in FIG. 11 can be grasped in advance by simulation, for example.

The driver circuit 1 operates in the following manner when the threshold voltage Vth of the switches 517 is set in this manner. For example, in the driver circuit 1, as for the area where the relationship between the duty ratio of the input input PWM signal and the output voltage of the GaN circuit in relation to the duty ratio is linear, that is, in a case where a signal with a pulse width which is equal to or greater than the sum of the rise time and fall time of the output PWM signal output from the GaN circuit has been input to the driver circuit 1, the charging time of the capacitors 516 in the control signal generating circuits 34 and 35 decreases, and the signals Vt1 and Vt2 are always at the Low levels. In this case, the driver circuit 1 does not perform the pulse width correction described above; as a result, the signals Hout and Lout input to the GaN circuit become signals representing waveforms similar to the high side input signal Hin and the low side input signal Lin.

On the other hand, in the driver circuit 1, as for the area where the relationship between the duty ratio of the input input PWM signal and the output voltage in relation to the duty ratio is non-linear, that is, in a case where a signal with a pulse width which is smaller than the sum of the rise time and fall time of the output PWM signal output from the GaN circuit has been input to the driver circuit 1, the charging time of the capacitors 516 in the control signal generating circuits 34 and 35 increases, and the signals Vt1 and Vt2 are at the High levels. In this case, the driver circuit 1 performs the pulse width correction described above, and the signals Hout and Lout input to the GaN circuit become signals representing waveforms obtained by performing the pulse width correction on the high side input signal Hin and the low side input signal Lin. In this case, the output voltage of the GaN circuit lowers. In this manner, in the driver circuit 1, the output voltage of the GaN circuit can be lowered only in the area where the duty ratio of the input PWM signal requires the pulse width correction (the area on the left side of the duty ratio denoted by a reference sign x illustrated in FIG. 11).

In addition, in the driver circuit 1, the signal Hout to be output to the GaN circuit is not generated by logical inversion of the signal Lout, but generated from the high side input signal Hin. In addition, in the driver circuit 1, the signal Lout to be output to the GaN circuit is not generated by logical inversion of the signal Hout, but generated from the low side input signal Lin.

Thereby, in the first embodiment, the signals Hout and Lout output by the driver circuit 1 can have an overlap (a state where two pulses are at the High logic levels simultaneously) with an amount which is equivalent to the amount of an overlap that the high side input signal Hin and the low side input signal Lin have. Then, since the signals Hout and Lout have the overlap, in the first embodiment, a current to flow at the time of switching of the GaN circuit can be reduced, and the power efficiency of the GaN circuit can be enhanced.

As mentioned above, according to the first embodiment, the driver circuit 1 is the driver circuit 1 to output, to an amplifier to output an output PWM signal representing an output voltage, a first drive signal and a second drive signal for driving the amplifier. On the basis of an input PWM signal which is a PWM signal input to the driver circuit 1, the driver circuit 1 outputs the first drive signal which is a PWM signal in phase with the input PWM signal, and the second drive signal which is a PWM signal in antiphase with the input PWM signal. On the basis of the first drive signal and the second drive signal output from the driver circuit 1, the amplifier outputs the output PWM signal which is a signal in antiphase with the first drive signal and in phase with the second drive signal. When the duty ratio of the input PWM signal input to the driver circuit 1 is lower than a predetermined duty ratio, the driver circuit 1 increases the pulse width of the first drive signal to be output described above inversely proportionally to the pulse width of the input PWM signal. Thereby, the driver circuit 1 according to the first embodiment can improve the linearity of the output voltage represented by the output PWM signal described above in relation to the duty ratio of the input PWM signal.

In addition, the driver circuit 1 includes: the signal control circuit 31 to generate a correction pulse having a pulse width inversely proportional to the length of time for which the input PWM signal is at the High level, when the duty ratio of the input PWM signal is lower than the predetermined duty ratio; and the addition circuit 32 to generate the first drive signal having an increased pulse width by logical operation of the correction pulse generated by the signal control circuit 31 and the input PWM signal. Thereby, the driver circuit 1 according to the first embodiment can generate the first drive signal with a pulse width increased on the basis of the duty ratio of the input PWM signal.

In addition, the signal control circuit 31 includes: the capacitor 516 that is capable of charging and discharging on the basis of whether the input PWM signal is at the High level or the Low level; and the switch 517 to switch the correction pulse to the High level or the Low level on the basis of the magnitude relationship between the voltage value of a voltage charged and discharged by the capacitor 516 and a preset threshold voltage. Thereby, the driver circuit 1 according to the first embodiment can generate the correction pulse precisely.

In addition, the threshold voltage is capable of being set to any voltage on the basis of the pulse width of the input PWM signal. Thereby, the driver circuit 1 according to the first embodiment allows a flexible setting as to whether to or not to generate the correction pulse on the basis of the pulse width of the input PWM signal.

In addition, the threshold voltage is set to an inter-terminal voltage of the capacitor 516 or higher, the inter-terminal voltage being a voltage in a case where the duty ratio of the input PWM signal is equivalent to the predetermined duty ratio. Thereby, the driver circuit 1 according to the first embodiment can switch whether to or not to generate the correction pulse using the predetermined duty ratio as a boundary regarding the switching.

In addition, the predetermined duty ratio is a duty ratio at a switching point between the area where the relationship between the duty ratio of the input PWM signal and the output voltage represented by the output PWM signal output from the amplifier is linear and the area where the relationship is non-linear. Thereby, the driver circuit 1 according to the first embodiment can switch whether to or not to generate the correction pulse using, as a boundary regarding the switching, the duty ratio at the switching point between the area where the relationship between the duty ratio of the input PWM signal and the output voltage represented by the output PWM signal output from the amplifier is linear and the area where the relationship is non-linear.

In addition, the predetermined duty ratio is a duty ratio of the input PWM signal at the time when the pulse width of the input PWM signal is smaller than the sum of the rise time and fall time of the output PWM signal output from the amplifier. Thereby, the driver circuit 1 according to the first embodiment can switch whether to or not to generate the correction pulse using, as a boundary regarding the switching, the duty ratio of the input PWM signal at the time when the pulse width of the input PWM signal is smaller than the sum of the rise time and fall time of the output PWM signal output from the amplifier.

In addition, the voltage generating circuit according to the first embodiment includes: the driver circuit 1; and an amplifier to output, on the basis of a first drive signal and a second drive signal output from the driver circuit 1, an output PWM signal which is a signal representing an output voltage, and is a signal in antiphase with the first drive signal. Thereby, the voltage generating circuit according to the first embodiment can improve the linearity of the output voltage represented by the output PWM signal described above in relation to the duty ratio of the PWM signal input to the driver circuit 1.

Note that the present disclosure allows modifications of any constituent elements in the embodiment, or omission of any constituent elements in the embodiment.

### INDUSTRIAL APPLICABILITY

The present disclosure can obtain a driver circuit that drives an amplifier to output an output PWM signal representing an output voltage, and can improve the linearity of the output voltage represented by the output PWM signal described above in relation to the duty ratio of an input PWM signal. The present disclosure is suited for being used for a driver circuit.

REFERENCE SIGNS LIST

1: Driver circuit; 31: Signal control circuit; 32: Addition circuit; 33: SW signal generating circuit; 34: Control signal generating circuit; 35: Control signal generating circuit; 36: Logical operation circuit; 37: Logical operation circuit; 38: OR circuit; 39: AND circuit; 41: Rising edge triggered T flip-flop circuit; 42: Rising edge triggered T flip-flop circuit; 43: Inverter circuit; 44: Inverter circuit; 45: AND circuit; 46: AND circuit; 61: Inverter circuit; 62: Inverter circuit; 63: AND circuit; 64: AND circuit; 65: AND circuit; 66: AND circuit; 67: OR circuit; 68: OR circuit; 71: Falling edge triggered T flip-flop circuit; 72: Inverter circuit; 73: Inverter circuit; 74: Inverter circuit; 75: AND circuit; 76: AND circuit; 77: AND circuit; 78: AND circuit; 79: AND circuit; 80: AND circuit; 81: OR circuit; 82: OR circuit; 511: Switch; 512: Switch; 513: Resistor; 514:

Resistor; 515: Resistor; 516: Capacitor (capacitor); 517: Switch; M1: Transistor; M2: Transistor

1. A voltage generating circuit including an amplifier to output an output PWM signal representing an output voltage and a driver circuit to output a first drive signal and a second drive signal for driving the amplifier, wherein
on a basis of a high side input signal obtained from an input PWM signal which is a PWM signal input to the driver circuit, the driver circuit outputs the first drive signal which is a PWM signal in phase with the high side input signal, and the second drive signal which is a PWM signal in antiphase with the high side input signal, and
when a duty ratio of the high side input signal is lower than a predetermined duty ratio, and a pulse width of the high side input signal is decreased, the driver circuit increases a pulse width of the outputted first drive signal before the pulse width of the high side input signal is decreased with respect to the pulse width of the first drive signal outputted in response to the high side input signal, and
the amplifier includes a first switching element that is turned on and off in response to the first drive signal output from the driver circuit, and a second switching element that is connected with the first switching element and turned on and off in response to a second drive signal outputted from the driver circuit, and the amplifier outputs the output PWM signal which is a signal in antiphase with the first drive signal and in phase with the second drive signal in response to on-and-off states of the first switching element and the second switching element.

2. The voltage generating circuit according to claim 1, comprising:
a signal control circuit to generate a correction pulse that increases a pulse width in response to a decrease in length of time for which the high side input signal is at a High level, when the duty ratio of the high side input signal obtained from the input PWM signal is lower than the predetermined duty ratio; and
an addition circuit to generate the first drive signal having an increased pulse width by logical operation of the correction pulse generated by the signal control circuit the high side input signal, a signal that is turned on and off at a rising edge of the high side input signal, and an inverted signal relative to said signal.

3. The voltage generating circuit according to claim 2, wherein
the signal control circuit includes:
a capacitor that is capable of charging and discharging on a basis of whether the input PWM signal is at a High level or a Low level; and
a switch to switch the correction pulse to a High level or a Low level on a basis of a magnitude relationship between a voltage value of a voltage charged and discharged by the capacitor and a preset threshold voltage.

4. The voltage generating circuit according to claim 3, wherein
the threshold voltage is capable of being set to any voltage in accordance with the pulse width of the input PWM signal.

5. The voltage generating circuit according to claim 3, wherein
the threshold voltage is set to an inter-terminal voltage of the capacitor or higher, the inter-terminal voltage being a voltage in a case where the duty ratio of the input PWM signal is equivalent to the predetermined duty ratio.

6. The voltage generating circuit according to claim 1, wherein
the predetermined duty ratio is a duty ratio at a switching point between an area where a relationship between the duty ratio of the input PWM signal and the output voltage represented by the output PWM signal output from the amplifier is linear and an area where the relationship is non-linear.

7. The voltage generating circuit according to claim 1, wherein
the predetermined duty ratio is a duty ratio of the input PWM signal at time when the pulse width of the input PWM signal is smaller than a sum of rise time and fall time of the output PWM signal output from the amplifier.
